(19) United States
(12) Patent Application Publication
(10) Pub. No.: US 2015/0219723 A1
(43) Pub. Date: Aug. 6, 2015

(54) Continuous Monitoring Architecture for Power Storage Systems

(71) Applicants: Donald H. Marvin, San Jose, CA (US); Oswaldo Torres, San Jose, CA (US); James W. Welch, Jr., Pine Grove, CA (US); Derek Ziemian, Mountain View, CA (US); Kurt Salloux, Palo Alto, CA (US)

(72) Inventors: Donald H. Marvin, San Jose, CA (US); Oswaldo Torres, San Jose, CA (US); James W. Welch, Jr., Pine Grove, CA (US); Derek Ziemian, Mountain View, CA (US); Kurt Salloux, Palo Alto, CA (US)

(21) Appl. No.: 14/189,428

(22) Filed: Feb. 25, 2014

Related U.S. Application Data
(60) Provisional application No. 61/936,835, filed on Feb. 6, 2014.
(60) Provisional application No. 61/943,371, filed on Feb. 22, 2014.

(51) Int. Cl. G01R 31/36

(52) U.S. Cl. CPC G01R 31/3606

(57) ABSTRACT

A battery monitoring system includes a central monitoring system and a set of individual battery selectors. The central monitoring system is electrically connected to the battery selectors and each of the battery selectors is connected to one or more batteries. In operation, commands are sent from the central monitoring system to the individual battery selectors so as to turn one on at a time. When the battery selector is on, test and response signals can be communicated between the one or more batteries connected to the battery selector and the central monitoring system. In some embodiments, the batteries include a reference circuit configured for calibration of battery tests.

### CROSS-REFERENCE TO RELATED APPLICATIONS

This application claims priority and benefit of U.S. provisional patent application 61/936,835 filed Feb. 6, 2014 and U.S. provisional patent application 61/943,371 filed Feb. 22, 2014. This application is related to commonly owned U.S. provisional patent application 61/944,256 filed Feb. 25, 2014. The disclosures of the above patent applications are hereby incorporated herein by reference.

### BACKGROUND

1. Field of the Invention

The Invention is in the field of battery monitoring.

2. Related Art

Batteries of all types have limited lifetimes. The ability to predict a battery's capacity to provide power is important in some applications. Measurements made on batteries have traditionally been made using handheld devices. As such, current technologies do not provide levels of reproducibility, precision, accuracy, and/or predictability that may be desired.

### SUMMARY

Various embodiments of the invention include a continuous monitoring system configured to monitor the states of batteries and similar power storage systems. The continuous monitoring system includes a central monitoring unit that is connected to a plurality of batteries. The batteries are optionally in series and/or parallel. The central monitoring unit is connected to the batteries via a plurality of a battery selectors disposed at the batteries. A separate battery selector is optionally assigned to each battery. Each of the batteries may include one or more electro-chemical cell.

The central monitoring unit is configured to send out interrogation signals and to detect resulting sense signals. The sense signals may be used to diagnose states of the batteries. The central monitoring unit is also configured to turn on and off members of the battery selectors such that individual batteries may be independently tested. In various embodiments, the central monitoring unit is configured to automatically detected impedance, resistance, voltage, current and/or temperature. These values may be measured as a function of time.

Various embodiments of the invention include a battery monitoring system comprising a signal bus including at least two sense signal conductors, at least two interrogation signal conductors and one or more logic conductors. In some embodiments only two sense signal conductors and only two interrogation signal conductors are required. The battery monitoring system further comprises a plurality of battery selectors, each of the battery selectors being configured to be electronically attached to a battery and each including switch logic configured to receive selector selection signals via the one or more logic conductors, the selector selection signals and switch logic being configured to select one of the plurality of battery selectors at a time for use in monitoring the respective battery attached to the selected one battery selector. The battery monitoring system further comprises at least two pole interfaces, each of the pole interfaces configured to communicate an interrogation signal to a battery pole and to receive a sense signal from the respective battery pole, the interrogation signal and sense signal being communicated via separate electrical conductors of a Kelvin probe, and an activation relay responsive to the switch logic and configured to control communication of the interrogation signals and sense signals between the two pole interfaces and the interrogation signal conductors and sense signal conductors, respectively. Optionally, the battery monitoring system further comprises a central monitoring unit electrically coupled to the plurality of battery selectors by the signal bus, the central monitoring unit configured to provide the interrogation signals to the plurality of battery selectors via the interrogation signal conductors, configured to receive the sense signals from the plurality of battery selectors via the sense signal conductors, and configured to send the selector selection signals to the plurality of battery selectors via the logic conductors so as to select an individual member of the plurality of battery selectors to monitor the respective battery connected thereto.

Various embodiments of the invention include a battery selector system, the battery selector system comprising switch logic configured to receive selector selection signals, the switch logic being configured to generate an output responsive to a match between an identify of the battery selector and the received selector selection signals; and two or more pole interfaces. In one example the battery selector system includes at least a first pole interface, a second pole interface and a third pole interface, each of the first, second and third pole interfaces being configured to be electrically connected to a respective battery pole using at least an interrogate conductor and a sense conductor of a Kelvin probe. The battery selector system further comprises an activation relay configured to open and close in response to the output of the switch logic, configured to allow communication of interrogation signals from an external bus to at least two of the first pole interface, the second pole interface and the third pole interface when the activation relay is closed, and configured to allow communication of sense signals from the external bus to or from least two of the first pole interface, the second pole interface and the third pole interface when the activation relay is closed. The battery selector system further comprises a pole selection relay configured to open and close in response to the output of the switch logic, and configured to select which two of the first pole interface, the second pole interface and the third pole interface are in electrical communication with the external bus responsive to the opening and closing of the pole selector relay.

Various embodiments of the invention include a central monitoring system comprising a bus interface configured to be electrically connected to a signal bus; interrogation signal logic configured to provide interrogation signals to the bus interface, the interrogation signals being configured for detecting a state of a battery monitored by the central monitoring unit. The central monitoring system further comprises sensing logic configured to receive sense signals from the battery, the sense signals being in response to the interrogation signals, the sensing logic being further configured to interpret the received sense signals and generate data characterizing a state of the battery based on the interpretation. The central monitoring system further comprising selection logic configured to generate selection signals to the bus interface, the selection signals being configured to select which one of a plurality of batteries receives the interrogation signals at a given time; and further comprising memory configured to store the data characterizing the state of the battery, for each of the plurality of batteries, and a microprocessor configured to execute at least the sensing logic.

### BRIEF DESCRIPTION OF THE DRAWINGS

FIG. 1 illustrates a continuous monitoring system, according to various embodiments of the invention.

FIG. 2 illustrates details of a central monitoring unit, according to various embodiments of the invention.

FIG. 3 illustrates details of a battery selector, according to various embodiments of the invention.

FIG. 4 illustrates an exemplary circuit of a battery selector switch, according to various embodiments of the invention.

FIGS. 5A and 5B illustrate alternative connections between a signal bus and battery selectors, according to various embodiments of the invention.

FIGS. 6A-6C illustrate embodiments including multiple cells within a battery.

FIG. 7 illustrates a distributed network of continuous monitoring systems, according to various embodiments of the invention.

FIGS. 8A and 8B illustrate embodiments of a battery selector including a calibration shunt, according to various embodiments of the invention.

### DETAILED DESCRIPTION

The systems disclosed herein are typically configured to monitor banks of batteries such as may be found in vehicles, energy storage systems or battery back-up systems. Each bank of battery may include a number of batteries. For example, it is not uncommon for a back-up system to include tens of batteries in series and/or parallel. The operation of a bank of batteries is dependent on the state of each battery within the bank. One poorly functioning battery can lead to degradation of an entire battery bank. Some embodiments of the invention reduce the impact of this problem by providing for early detection of poor battery operation.

The systems and methods discussed herein can be applied to a wide variety of different battery types. For example, they may be applied to conventional Lead-Acid batteries, Lithium-ion batteries, single use batteries, rechargeable (secondary) batteries, and/or the like.

As used herein, the phrase continuous monitoring is used to refer to a system that maintains continuous physical connection to the device being tested. While the physical connection is being continuously maintained, actual measurements may be dispersed in time, with periods of no measurement there between. For example, continuous monitoring may include a Kelvin probe that is securely attached to a pole of a battery. The Kelvin probe includes interrogation conductors configured to apply an interrogation signal across a load, and also sense conductors configured to detect a response signal that may result from the interrogation signal. Kelvin probes use four wires (conductors) to make impedance measurements. One method of making low impedance measurements is to force current through two conductors while measuring a resultant voltage with the other two conductors. Since the voltage measurement draws insignificant amounts of current, potential errors created by any resistance or change in resistance in either the current force or in the voltmeter test leads are negligible. Using a securely attached Kelvin probe allows for consistent high precision measurements when needed. Secure attachment includes an attachment whose conductivity is not significantly changed by inadvertent movements in wire position and means that the position of the probe relative to the battery pole being measured is fixed. Secure attachment can be achieved using threaded connectors, nuts, bolts, rivets, etc.

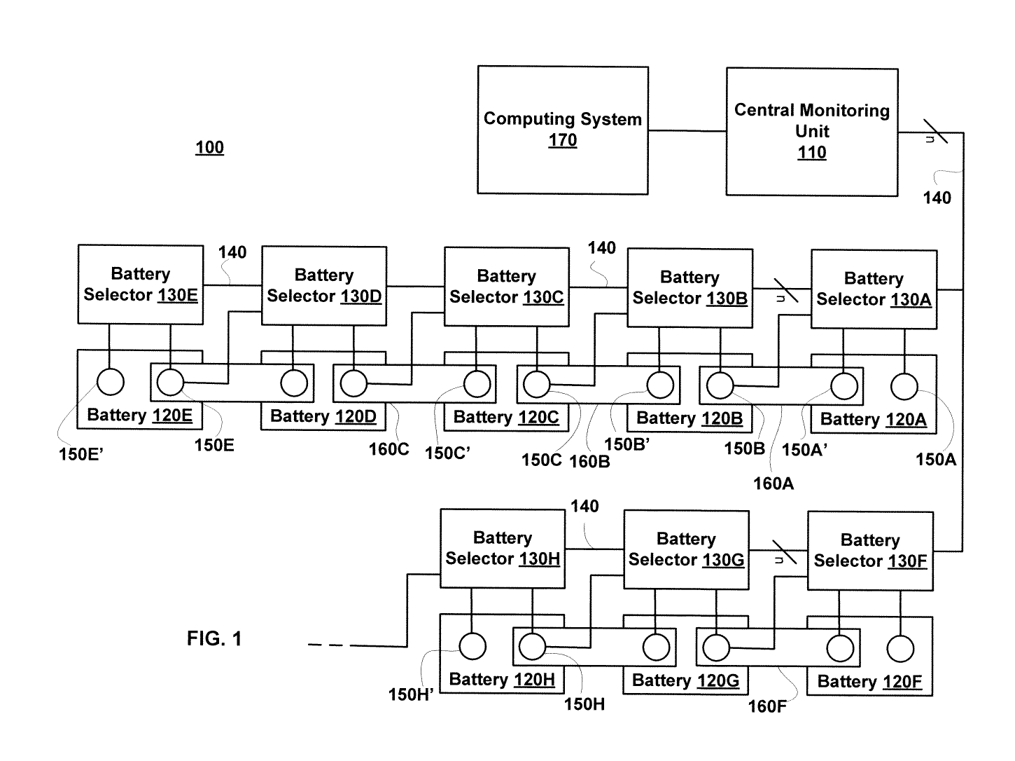

FIG. 1 illustrates a Continuous Monitoring System 100, according to various embodiments of the invention. Continuous Monitoring System 100 includes a Central Monitoring Unit 110 and a plurality of Battery Selectors 130, individually designated 130A-130H, etc. In use, the Battery Selectors 130 are connected to a plurality of Batteries 120, individually designated 120A-120H, etc. Continuous Monitoring System 100 may include different numbers of Battery Selectors 130. For example, in various embodiments Continuous Monitoring System 100 includes at least 4, 8, 16, 32, 64, 128, 240 or 260 Battery Selectors 130. In the embodiments illustrated by FIG. 1 each Battery Selector 130 is configured for the monitoring of a single battery. However, in alternative embodiments a single Battery Selector 130 is configured for monitoring more than one battery or a subset of electrochemical cells with a battery.

Battery Selectors 130 are electrically connected to Central Monitoring Unit 110 by a Signal Bus 140. Signal Bus 140 includes multiple (n) conductors in parallel. Each of these conductors may include, for example, a single wire or a set of wires in series. The number of conductors include in Signal Bus 140 is optionally dependent on the quantity of Battery Selectors 130 within Continuous Monitoring System 100. However, Signal Bus 140 includes at least two sense signal conductors, at least two interrogation signal conductors and one or more logic conductors. In some embodiments, Signal Bus 140 includes two interrogation conductors, 2 sense conductors and a number of logic conductors sufficient to individually select and control each of Battery Selectors 130. The two interrogation signal conductors are configured to communicate an interrogation signal to Kelvin probes disposed across a load. The two sense signal conductors are configured to communicate sense signals from the Kelvin probes. The sense signals are typically in response to the probe signals. As discussed further elsewhere herein, the logic conductors are configured for selecting and controlling members of the Battery Selectors 130. Battery Selectors 130 may be connected to Signal Bus 140 in series or in parallel. For example, as illustrated in FIG. 1, Battery Selectors 130A-130E are in series with respect to each other, and are in parallel with respect to Battery Selectors 130E-130H.

Each of the Battery Selectors 130 is connected to Poles 150 of at least one of Batteries 120. Poles 150 are individually labeled 150A, 150A′, 150B, 150B′, etc. For example, as illustrated in FIG. 1, Battery Selector 130A is connected to Poles 150A and 150A′ of Battery 120A. Poles 150A and 150A′ include the anode and cathode of Battery 120, or vice versa. The connection at Poles 150 includes at least a secure two wire Kelvin probe and the connection is made at a pole on each of Battery 120.

Batteries 120 are connected together via conductive Straps 160. Straps 160 are individually labeled 160A, 160B, 160C, etc. Straps 160 are optionally used to connect a large number of Batteries 120 in a bank. Each of Battery Selectors 130 are optionally also configured to connect to a third Pole 150 of an adjacent member of Batteries 120. For example, in the embodiments illustrated by FIG. 1, Battery Selector 130B is connected to Poles 150B and 150B′ of Battery 120B and also connected to Pole 150C of Battery 120C. Using this configuration, monitoring of Battery 120B can be performed with and without Strap 160B included as part of the load. This allows Continuous Monitoring System 100 to distinguish between electrical characteristics of Battery 120B and Strap 160B. Both defective Straps 160 and defective Batteries 120 can be identified.

Continuous Monitoring System 100 optionally further includes a Computing System 170. Computing System 170 is configured to communicate with Central Monitoring Unit 110 and includes a computer, non-volatile memory, a user interface, etc. As is discussed further elsewhere herein, Computing System 170 is configured to manage Central Monitoring Unit 110, store collected battery data, and/or further analyze the collected battery data. Computing System 170 is optionally coupled to Central Monitoring Unit 110 via a communication network such as the internet.

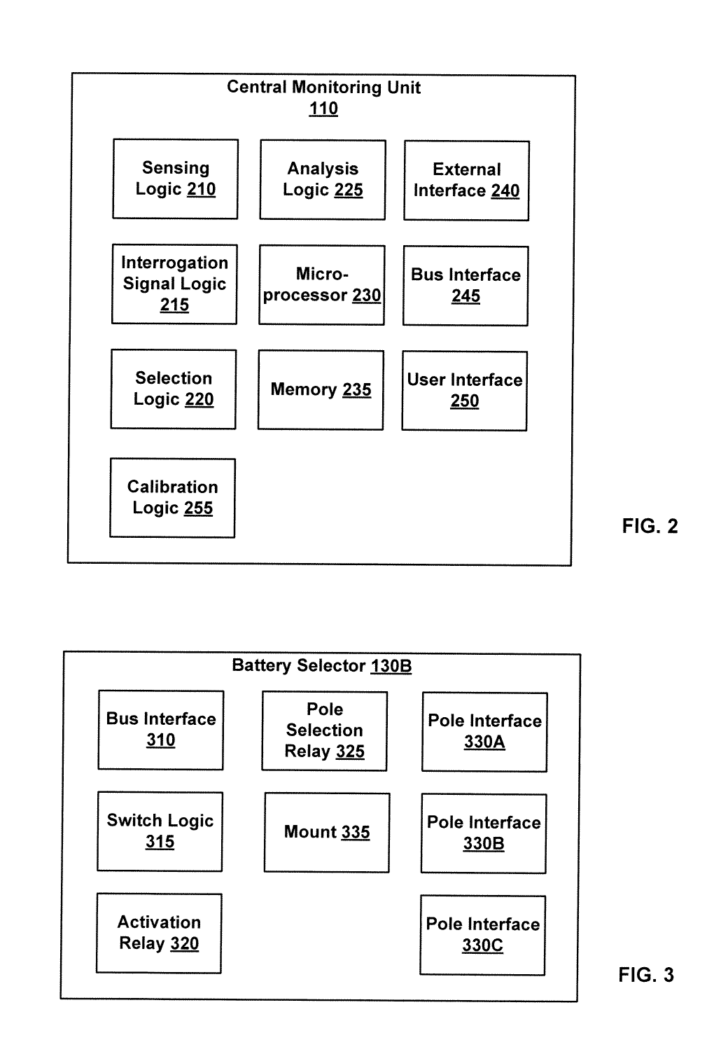

FIG. 2 illustrates details of Central Monitoring Unit 110, according to various embodiments of the invention. Central Monitoring Unit 110 includes Sensing Logic 210, Interrogation Signal Logic 215, Selection Logic 220 and optional Analysis Logic 225. These logic elements include hardware, firmware and/or software stored on a non-transient computer readable medium, and are configured, by arrangement of logic functions, to perform specific functions as described herein. These logic elements are optionally executed using a Microprocessor 230. Microprocessor 230 may be a general purpose microprocessor programmed (e.g., configured) for particular purposes using software or firmware, or may be a specific purpose microprocessor.

Interrogation Signal Logic 215 is configured to provide the interrogation signals to the plurality of Battery Selectors 130 via the interrogation signal conductors of Signal Bus 140. These interrogation signals may include DC voltages and/or time dependent voltages over a wide range of frequencies. For example, in some embodiments the interrogation signals include time dependent signals having a frequency between 70 and 100 Hz. In some embodiments the interrogation signals include time dependent signals having a frequency between 0.01-1 Hz, 0.1 Hz and 1 Hz, 1 Hz and 10 Hz, 10 Hz and 50 Hz, 50 Hz and 120 Hz, 66 Hz and 100 Hz, 120 Hz and 500 Hz, 500 Hz and 1000 Hz, 1000 Hz-2500 Hz, or any combination thereof. Interrogation signals of different frequencies are optionally used to monitor a single battery. For example, different types of battery malfunctions may be detected using different frequencies. Further different frequencies may be used to interrogate batteries of different types or sizes. In some embodiments the frequencies of interrogation signals are adjusted to avoid frequencies at which electrical noise is present. For example, Interrogation Signal Logic 215 may be configured to detect noise within a battery system and to automatically select interrogation frequencies that are easily distinguished from the frequencies of the detected noise.

Interrogation Signal Logic 215 optionally includes a digital signal generator and filters configured to control the generated frequency range. In some embodiments Interrogation Signal Logic 215 is configured to automatically select interrogation frequencies based on a battery type and/or size. For example, Interrogation Signal Logic 215 may include an input for user to designate a battery type and/or size. Higher frequencies are optionally automatically selected for smaller batteries.

Sensing Logic 210 is configured to receive response signals from the plurality of Battery Selectors 130 via sense signal conductors of the Signal Bus 140. The received response signals are typically responsive to the interrogation signals provided to the Battery Selectors 130 by interrogation Signal Logic 215. As such, the sensed response signals represent the response of a load to the interrogation signals. The load is typically one of Batteries 120 and/or Straps 160. Sensing Logic 210 typically includes an analog to digital converter. In various embodiments, the analog to digital converter is configured to detect DC signals and/or time dependent signals having frequency between zero and 5KH, or any of the other signal frequency ranges discussed herein.

Sensing Logic 210 is optionally also configured to receive noise signals from the plurality of Battery Selectors 130 via sense signal conductors of the Signal Bus 140. These noise signals may be generated by, for example, a charging device connected to the Batteries 120 and/or an electrical load powered by the Batteries 120. The noise signals are normally present in the absence of any interrogation signal. Sensing Logic 210 may generate data characterizing the frequencies and/or amplitudes of the received noise signals. In some embodiments, Sensing Logic 210 is configured to identify frequency ranges including greater and lesser amounts of noise. Interrogation Signal Logic 215 is optionally configured to generate interrogation signals in those frequency ranges in which the lesser amounts of noise are found.

Data generated using Sensing Logic 210 is optionally communicated to devices outside of central Monitoring Unit 110 for storage and/or further analysis.

Selection Logic 220 is configured to generate selector selection signals. The selection signals are configured to select individual Battery Selectors 130. For example, they may be configured to perform this function by encoding specific digital identifiers or switch signals. The selection signals can be serial or parallel signals. Selection Logic 220 is further configured, e.g., by the inclusion of appropriate logic and conductors, to send the selector selection signals to the plurality of Battery Selectors 130 via the logic conductors of Signal Bus 140. Typically, the selection signals result in activation of just one of the Battery Selectors 130, so as to select an individual member of the plurality of battery selectors to monitor the respective battery(ies) connected thereto. The selection signals are configured to select which one member of Batteries 120 receives the interrogation signals at a given time. The selection signals cause the sense signals to be received by the Central Monitoring Unit 110 to be from the same one member of Batteries 120, at the same given time.

The selection signals generated and sent by Selection Logic 220 are optionally further configured to select a specific set of battery poles to interrogate. For example, a first selection signal may be configured to select Battery Selector 130B and Poles 150B and 150B′ of Battery 120B. A second selection signal may be configured to select Battery Selector 130B and Pole 150B of Battery 120B and Pole 150C of Battery 120. The second selection signal results in Strap 160B being included in the interrogated load.

The selection signals generated and sent by Selection Logic 220 are optionally further configured to select between testing between (i.e., across) battery poles or, in the alternative, testing across a calibration shunt. For example, first selection signals may include an encoding configured such that interrogation signals are received by Poles 150A and 150A′ of Battery 130A, second selection signals may include an encoding configured such that interrogation signals are received by Pole 150B of Battery 120B and Pole 150A′ of Battery 120A, and third selection signals may include an encoding configured such that interrogation signals are received by a calibration shunt within a specific member of Battery Selectors 130.

Selection Logic 220 is typically configured to cycle through Battery Selectors 130, so as to monitor each of Batteries 120 one at a time. The period (e.g., length) of time spent analyzing each individual member of Batteries 120 may depend on a wide variety of factors. For example, measurements over tens of minutes or hours can be useful when working at frequencies less than 1 Hz. For example, in various embodiments measurements can be from 0.5 seconds up to 10 sec., 25 sec, 60 sec, 5 min., 10 min., 30 min., 1 hour, 5 hours, 12 hours or a day. Continuous Monitoring System 100 is configured for Battery Selectors 130 to stay connected to their respective Batteries 120 between periods in which the respective Batteries 120 are being tested using Interrogation Signal Logic 215 and/or Sensing Logic 210. For measurements longer than a few minutes, the temperature of the Battery 120 under test is optionally monitored such that variations in temperature may be adjusted for in the measurement. Methods of measuring temperature are discussed in the patent applications cited herein.

Individual members of Batteries 120 may be measured for different lengths of time. For example, all batteries in a bank may be tested for less than one minute every day, while some batteries are tested for times longer than a minute. The longer tests, which may be for times over 1 minute, 10 minutes, 15 minutes, 1 hour, 5 hours, 12 hours or a day, may be applied to a battery at intervals of greater than once a day or after a battery has shown initial signs of a degraded state. For example, once a battery has been found to have a problem using a shorter test, the nature of the problem may be investigated using a longer test.

Analysis Logic 225 is configured to process the data produced by Sensing Logic 210. This processing includes detection of historical trends in the state of individual and/or changes in individual batteries that indicate changes in battery health. One example of the types of analysis that may be performed by Analysis Logic 225 are found in co-pending patent application Ser. No. 12/945,886 filed Nov. 14, 2010, Ser. No. 13/284,788 filed Oct. 28, 2011, Ser. No. 12/963,500 filed Dec. 8, 2010; and U.S. Pat. Nos. 6,411,098, 6,990,422, 7,078,965 and 7,253,680. The disclosures of the above patents and patent applications are hereby included herein by reference. In some embodiments, Analysis Logic 225 is configured to control Interrogation Signal Logic 215 in response to received data. For example, Analysis Logic 225 may receive a first set of data from Sensing Logic 210 and based on the analysis of this data determine that additional tests are warranted for one or more of the batteries represented by the first set of data. Based on this determination, Analysis Logic 225 may be configured to request that the Interrogation Signal Logic 215 generate signals to perform these additional tests. The data processing performed by Analysis Logic 225 may result in a recommendation that one or more of Batteries 120 be replaced and/or an estimate of remaining useful life for one or more of Batteries 120.

Central Monitoring Unit 110 further includes Memory 235. Memory 235 includes non-transitory memory such as Read Only Memory (ROM), Random Access Memory (RAM), a hard drive, and/or the like. Memory 235 may be configured for, for example, storing data generated by Sensing Logic 210, storing an output of Analysis Logic 225 that results from processing this data, historical data regarding each of Batteries 120, configuration data such as numbers and identifiers of Battery Selectors 130, events such as replacements of members of Batteries 120, noise data, temperature data, and/or the like. Memory 235 may be configured for storing such data by way of, for example, appropriate indexing, file structures, data structures, directory structures, and/or the like.

Central Monitoring Unit 110 further includes an optional External Interface 240. External Interface 240 is a digital interface configured for communication between Central Monitoring Unit 110 and external devices. This communication can include state history of Batteries 120, a log of tests performed on Batteries 120, results of analysis performed using Analysis Logic 225, control instructions configured to control Central Monitoring Unit 110, raw battery data, and/or the like. In some embodiments, External Interface 240 includes a network interface, such as an Ethernet port, configured to communicate with a local computer network or the internet.

Bus Interface 245 includes one or more electrical interface configured for attaching Signal Bus 140 to Central Monitoring Unit 110. In some embodiments, Bus Interface 245 includes one connector for all conductors of Signal Bus 140. In some embodiments, Bus Interface 245 includes one connector for sense signal conductors and a separate connector for interrogation signal conductors. Other connector configurations are possible. The connectors of Bus Interface 245 are optionally configured to connect to shielded cables. In some embodiments, Central Monitoring Unit 110 includes more than one Bus Interface 245 each configured to connect a separate independent Signal Bus 140.

Central Monitoring Unit 110 further includes an optional User Interface 250. User Interface 250 is configured for a user (a person) to interact with Central Monitoring Unit 110. User Interface 250 can include a display, a keyboard, a touchscreen, a pointing device, a USB port, a speaker, a microphone, warning lights, and/or the like. For example, User Interface 250 may include controls configured for a user to select test parameters and tests to be performed on Batteries 120. User Interface 250 may include logic configured to provide the user with an indication that the operation of a member of Batteries 120 degraded and should be replaced before the degraded battery has a significant negative impact on other members of Batteries 120. This indication may be provided using a warning light or on the display.

Central Monitoring Unit 110 optionally further includes Calibration Logic 255. Calibration Logic 255 is configured for calibrating measurements of Batteries 120 using Central Monitoring Unit 110. For example, Calibration Logic 255 is configured to adjust signals received from sense signal conductors based on one or more factors. These factors may include, for example, temperature, battery type, a calibration standard, terminal connections, battery size, battery chemistry, and/or the like. The adjustment of signals permits normalization, and thus comparison, of signals received under different conditions. The normalization can be based on a theoretical or an experimentally derived calibration curve. Calibration Logic 255 includes hardware, firmware and/or software stored on a computer readable medium.

In some embodiments, Calibration Logic 255 is configured to compensate for a battery temperature based on an expected temperature response of a battery state. For example, the output voltage or impedance of a battery may change with temperature and Calibration Logic 225 may compensate for this variation in order to normalize measurements taken at different times. Detection of battery temperature may occur on the battery or within members of Battery Selectors 130.

In some embodiments, Calibration Logic 255 is configured to compensate for the length of Signal Bus 140, the quality of connections within measurement circuits, or other electrical characteristics of battery measurements. This can be accomplished, for example, by using a calibration shunt disposed within members of Battery Selectors 130. The calibration shunt provides a known impedance disposed within each Battery Selector 130. This known impedance can be tested using essentially the same circuits used to measure each battery. By comparing the known impedance with the tests across the calibration shunt, the effects of the testing circuits on the tests can be approximated. Calibration Logic 255 is optionally configured to account for these effects in making battery measurements. Further details of calibration shunts, according to various embodiments of the invention, are discussed elsewhere herein. Calibration shunts may be used to calibrate signals generated across loads between battery Poles 150 and/or across Straps 160.

FIG. 3 illustrates details of a Battery Selector 130B, according to various embodiments of the invention. Battery Selector 130B includes at least one Bus Interface 310 configured to connect to Signal Bus 140. More than one Bus Interface 310 may be used to daisy-chain Battery Selectors 130 together. In typical embodiments, Bus Interface 310 has characteristics matching those of Bus Interface 245. For example, Bus Interface 310 may be configured to receive shielded cables and interrogation signal conductors may be shielded separately from sense signal conductors.

Battery Selector 130 further includes Switch Logic 315, an Activation Relay 320 and an optional Pole Selection Relay 325. Switch Logic 315 is configured to receive selector selection signals via Bus Interface 310. Switch Logic 315 interprets the selector signals and operates Activation Relay 320 and/or Pole Selection Relay 325 in response to the received selector signals. Switch Logic 315 may include, for example, a set of logic gates configured to properly convert the selector selection signals to control signals for the relays.

In some embodiments, Switch Logic 315 includes memory configured to store an identifier of the particular member of Battery Selectors 130. This memory can include digital data storage, or a set of switches (e.g., dip switches). The identifier is preferably unique to each of Battery Selectors 130 connected to the logic conductors of the same Signal Bus 140. The identifier may be manually or automatically set. For example, a set of dip (dual inline package) switches may be manually set. Alternatively, an identifier for each Battery Selector 130B may be automatically generated by signals communicated through logic conductors of Signal Bus 140. In some embodiments, Switch Logic 315, in a setup mode, is configured to receive a first identifier, store that identifier and then send a next identifier in sequence to the next Battery Selector 130 in a daisy chain.

The output of Switch Logic 315 is configured (e.g., has sufficient current and voltage) to switch Activation Relay 320 and Pole Selection Relay 325. The output is optionally driven by current received through the logic conductors of Signal Bus 140. The switching of Activation Relay 320 to an ON state is responsive to a match between the identity of the battery selector, e.g., Battery Selector 130B, and received selector selection signals. If there is a match, then Activation Relay 320 is turned on and interrogation signal can reach the member(s) of Batteries 120 connected to Battery Selector 130B.

In some embodiments Activation Relay 320 is a four pole relay configured to switch four conductors comprising two interrogation signal conductors and two sense signal conductors. The four pole relay is switched in unison so that all are ON or all OFF at the same time. (The ON condition is considered the position in which the switch circuit is closed such that current can flow through the switch.) Activation Relay 320 may be configured to switch greater numbers of conductors. In various embodiments, the Activation Relay 320 is configured to control a standoff voltage of at least 50, 75, 100, 120, 150, 250, 500, 750 or 1000 Volts DC, or any range between these values, or more than 1000 Volts DC. The upper limit of control is determined by relay technology, which is expected to improve further in the future. In other embodiments Activation Relay 320 is configured to control a standoff voltage of between 5 and 50 Volts. Activation Relay 320 can comprise one or more physical devices.

Pole Selection Relay 325 is configured for selecting different pairs of battery Poles 150 where a member of Battery Selector 130 is connected to more than two of battery Poles 150. For example, considering Battery Selector 130B as illustrated in FIG. 1, Battery Selector 130B is connected to battery Poles 150B, 150B′ and 150C. Battery Selector 130B may be used to test Battery 120B using a pair of these battery Poles 150. Pole Selection Relay 325 is configured to select between a pair of battery Poles 150 to test Battery 120B and a pair of battery Poles 150 to include Strap 160B in a test. For example, a first state of Pole Selection Relay 325 may result in testing across battery Pole 150B and battery Pole 150B′, and a second state of Pole Selection Relay 325 may result in testing across battery Pole 150B and battery Pole 150C. The second state includes Strap 160B in the tested circuit (the load). As such, electrical characteristics of Strap 160B may be distinguished from those of Battery 120B. Alternatively, a first state of Pole Selection Relay 325 may result in testing between battery Pole 150B and battery Pole 150B′, and a second state of Pole Selection Relay 325 may result in testing between battery Pole 150B′ and battery Pole 150C. In various embodiments, the Pole Selection Relay 325 is configured to control a standoff voltage of at least 25, 50, 75, 100, 120, 150, 250, 500, 750 or 1000 Volts DC, or any range between these values, or more than 1000 Volts DC.

Battery Selectors 130 further include two or more Pole Interface 330, individually identified as 330A, 330B, 330C, etc. Pole Interfaces 330 are configured for connecting conductors between Battery Selectors 130 and battery Poles 150. Each of Pole Interfaces 330 include a connector, at least two sense conductors and at least two interrogation conductors. The sense conductors and interrogation conductors are configured to be continuously attached to battery Poles 150 and optionally are configured as a Kelvin probe. The different Pole Interfaces 330 may include separate connectors or one or more shared connectors. Activation Relay 320 is configured to allow communication of interrogation signals from Signal Bus 140 to at least two of the Pole Interface 330A, Pole Interface 330B and Pole Interface 330C when Activation Relay 320 is closed (ON).

Battery Selector 130B optionally further includes a Mount 335 configured to securely attach Battery Selector 130B to a bank of batteries. This mount is configured for continuous attachment and can include, for example, openings for bolts or screws; a hinge, rivets, snaps, bolts, magnets, or other secure connections. The secure connections are secure in that they are configured for being mounted near the batteries being tested for periods of time longer than a hand held testing device would be attached to a battery being tested, e.g., more than a day. In some embodiments, the secure attachment is such that Battery Selector 130B is maintained in a secure position relative to Battery 120B without human invention.

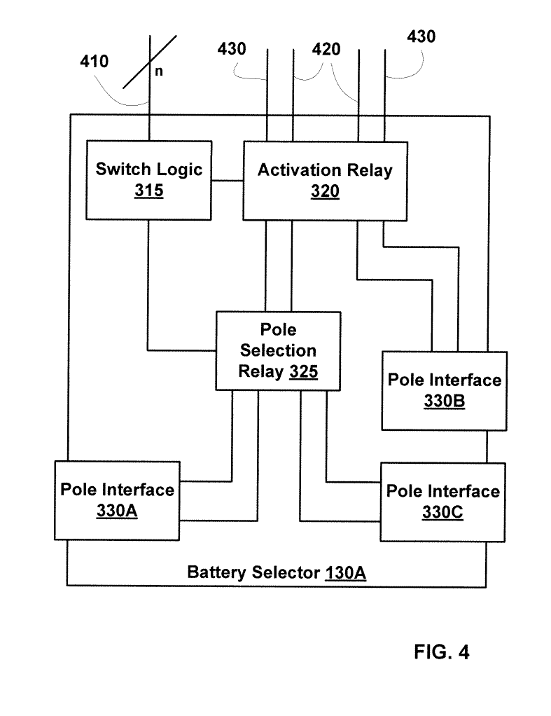

FIG. 4 illustrates an exemplary circuit of a battery selector switch, according to various embodiments of the invention. In this circuit, Logic Conductors 410 of Signal Bus 140 are configured to communicate signals from Central Monitoring Unit 110 to Switch Logic 315. Likewise, Sense Conductors 420 and Interrogation Conductors 430 are figured to communicate between and Central Monitoring Unit 110 and Activation Relay 320 of Battery Selector 130. Switch Logic 315 is configured to communicate control signals to Activation Relay 320 and Pole Selection Relay 325. When the switches within Activation Relay 320 are in the closed (ON) state one pair of Interrogation Conductor 430 and Sense Conductor 420 is electrically coupled to Pole Selection Relay 325, and a second pair of Interrogation Conductor 430 and Sense Conductor 420 is electrically coupled to Pole Interface 330B. Dependent on the control signal received from Switch Logic 315, Pole Selection Relay 325 is configured to electrically couple, one at a time in the alternative, the Interrogation Conductor 430 and Sense Conductor 420 (via Activation Relay 320) to Pole Interface 330A and Pole Interface 330C.

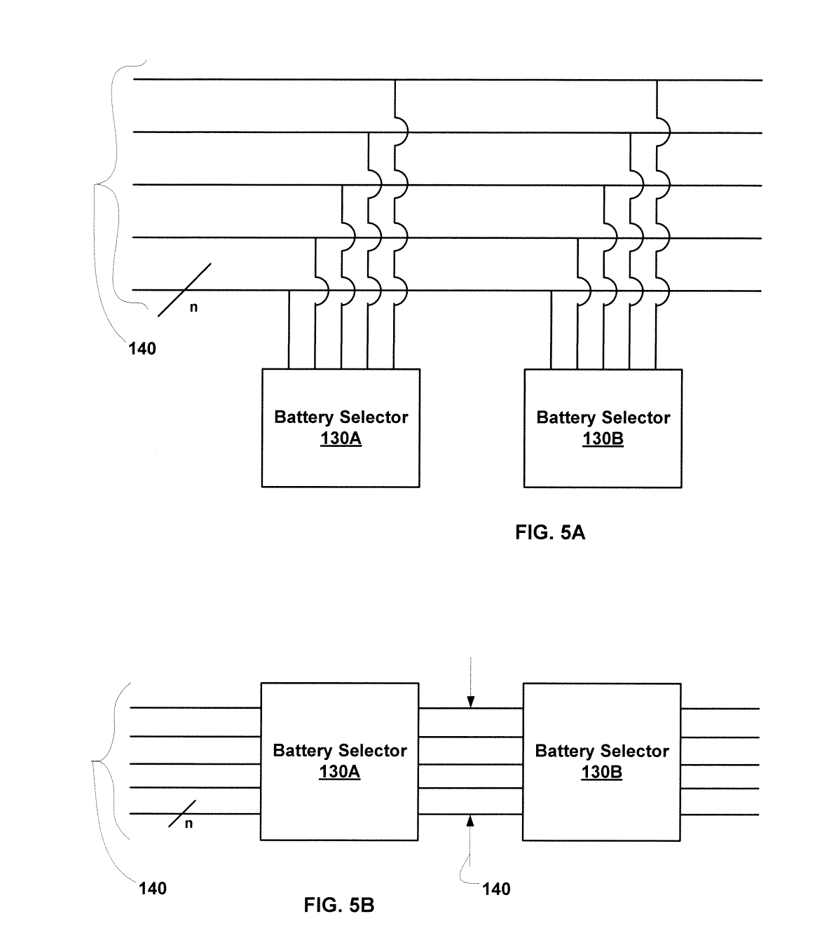

FIGS. 5A and 5B illustrate alternative connections between Signal Bus 140 and Battery Selectors 130. In FIG. 5A Signal Bus 140 includes a “T” connection external to Battery Selector 130A and a “T” connection external to Battery Selector 130B. In these embodiments Battery Selector 130A needs only one connection to Signal Bus 140. In FIG. 5B Signal Bus 140 is coupled to Battery Selector 130A in two positions. The first position includes conductors from Central Monitoring Unit 110 and the second position includes conductors to Battery Selector 130B. In these embodiments, Battery Selectors 130 are “daisy-chained” together in series and Battery Selector 130A includes at least two connections to Signal Bus 140.

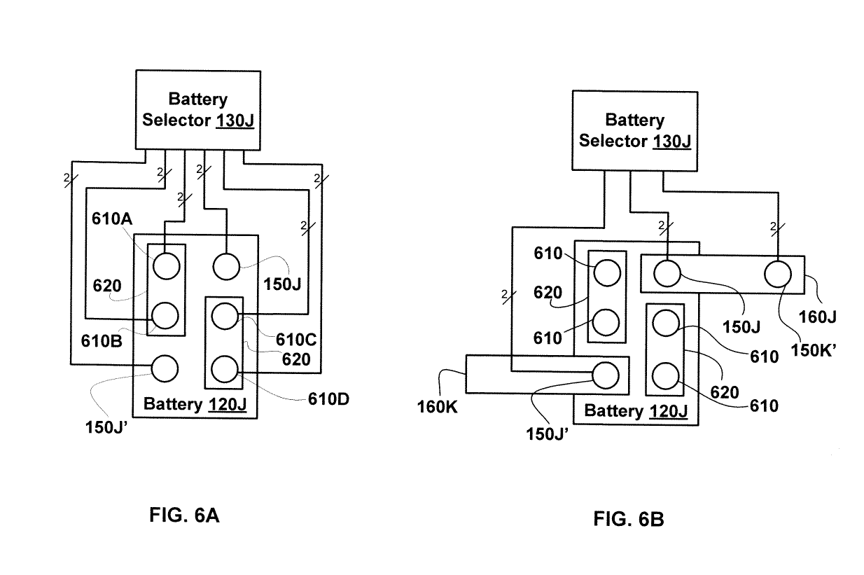

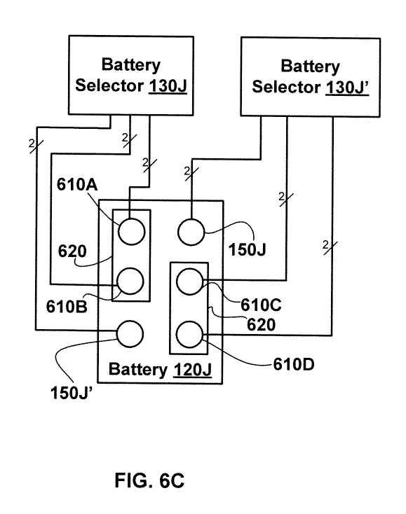

FIGS. 6A-6C illustrate embodiments including multiple separately accessed cells within a Battery 120J. In these embodiments Battery Selectors 130 may be configured to connect to additional Poles 150. For example, FIG. 6A illustrates a Battery 120J that includes Poles 150J and 150J′ and in addition Poles 610A-610D. Poles 610A-610D are electrically coupled by Straps 620. Straps 620 may be internal or external to Battery 120J. In FIG. 6A Battery Selector 130J includes a separate connection to each of the Poles 150J, 150J′ and 610A-610D. (Each of the connections includes at least a Sense Conductor and an Interrogation Conductor 430, and this embodiment of Battery Selector 130J includes at least six Pole Interface 330 for making these connections.) These separate conductors allow for testing of the multiple battery cells and also the Straps 620 connecting the poles within Battery 120J. In the embodiments wherein more than three Poles (150/610), Switch Logic 315 and Pole Selection Relay 325 are configured to switch and select among a corresponding number of Pole Interface 330. In FIG. 6A Straps 160J and 160K are not shown for clarity.

FIG. 6B illustrates embodiments in which a Battery 120J includes multiple cells and more than two Poles 150/610. In the embodiments illustrated, Battery Selector 130J is configured to connect with Poles 150J and 150J′. Battery Selector 130J is optionally further configured to connect with additional poles, such as Pole 150K′ of an adjacent Battery 130. Testing between these Poles 150 results in testing of all the cells within Battery 120J and the Straps 620 as a single unit. A similar approach may be taken for testing several batteries in series. For example, two batteries in series may be tested using two Kelvin probe test leads by connecting the test leads to the first and last Poles 150 of the series. While FIG. 6A illustrates connections made to all Poles 150/610, and FIG. 6B illustrates connections made to two Poles 150, in alternative embodiments some but not all of the Poles 610 may be connected to Battery Selector 130J.

FIG. 6C illustrates the use of two different Battery Selectors 130 (indicated as 130J and 130J′) to monitor multiple Poles 150/610 of one Battery 120J. In these embodiments, testing may occur between any pair of Poles 610A, 610B and 150J′ using Battery Selector 130J. Testing may occur between any pair of Poles 150J, 610C and 610D using Battery Selector 130J′. Further, in some embodiments, Battery Selector 1301 and 130J′ are configured such that a load can be measured between a pole connected to Battery Selector 130J and a pole connected to Battery Selector 130J′. For example, a measurement may be made between Poles 610A and 610B or between Poles 150J and 150J′. In these embodiments, Battery Selectors 130J and 130J′ are both selected at the same time. Their respective Activation Relays 320 are configured accordingly. As illustrated by FIGS. 6A-6C, Batteries 120 including additional Poles 150/610 may be monitored using Battery Selectors 130 including a corresponding number of Pole Interface 330, or using multiple Battery Selectors 130. These approaches can be applied to Batteries 120 having a number of Poles 150/610 different than those examples illustrated.

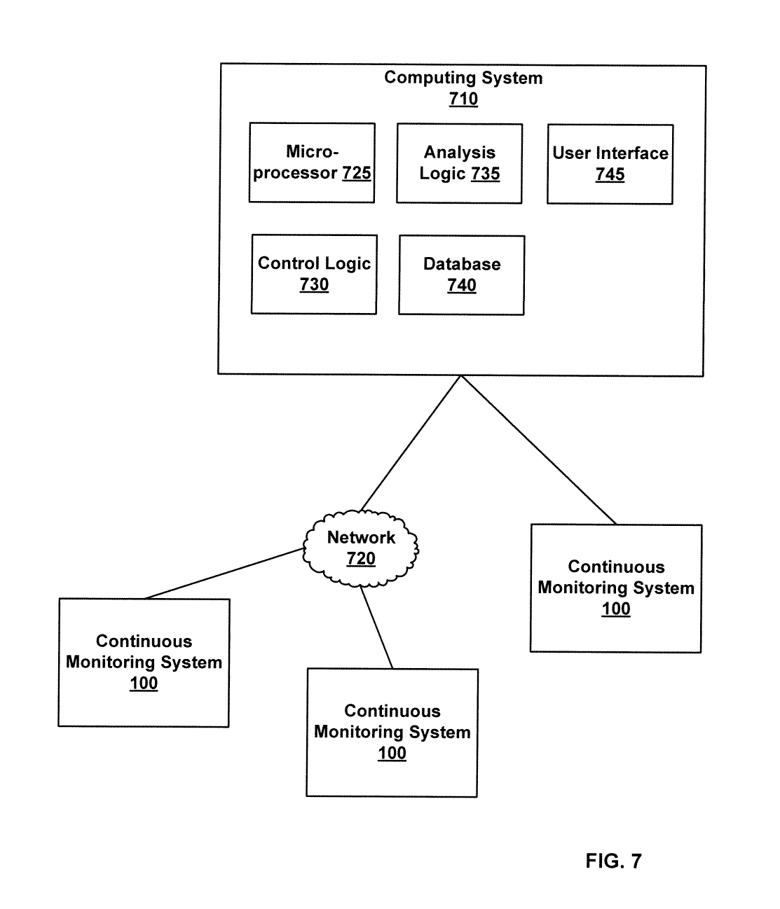

FIG. 7 illustrates distributed Continuous Monitoring Systems 100 connected to a Computing System 710 either directly or through a communication Network 720, e.g., through the internet, a telephone network and/or a local network. Each of Continuous Monitoring System 100 includes a bank of Batteries 120, Battery Selectors 130 and at least one Central monitoring Unit 110. The Continuous Monitoring Systems 100 may be distributed across a wide area.

Computing System 710 comprises one or more computing devices, such as personal computers or servers. These computing devices include at least one Microprocessor 725 configured to execute logic within Computing System 710. Microprocessor 725 may include a customized electronic circuit such as a programmable gate array. Microprocessor 725 may include a general purpose processor programmed to perform specific functions using the logic discussed herein.

Computing System 710 includes Control Logic 730 configured for controlling each of Continuous Monitoring Systems 100. Control Logic 730 is configured for sending control signals to one or more Continuous Monitoring system 100. In various embodiments, these control signals are configured to cause Continuous Monitoring System 100 to perform specific tests on Batteries 120, schedule tests on batteries, upload battery state data (current and/or historical), upload or set alerts and/or warnings, upload log data, and/or the like. For example, in some embodiments, Control Logic 730 is configured to receive battery state data from one of Central Monitoring Systems 100 and, in response, direct specific tests for the Batteries 120 within that Central Monitoring System 100.

Computing System 710 further includes Analysis Logic 735, which is configured to analyze battery data received from one or more Central Monitoring System 100. Analysis Logic 735 is configured to determine the present and/or future condition of individual Batteries 120. This determination may be based on changes in battery state over time, based on a single scheduled test for one of Batteries 120, and/or based on advanced tests on one of Batteries 120. For example, in some embodiments, Analysis Logic 735 may, based on changes to a battery's state over time, determine that advanced (e.g., additional or non-routine) tests are required for a battery. Then based on results of these advances tests determine an expected lifetime for the battery.

Computing System 710 further typically includes a Database 740. Database 740 includes computer applications and non-volatile storage for the storage, organization, retrieval and analysis of data. The data stored in Database 740 can include historical battery state data received from Continuous Monitoring System 100, The data can also include configuration data regarding the numbers and identities of Batteries 120 monitored using Continuous monitoring Systems 100. Database 740 is typically accessible to Analysis Logic 735 and/or Control Logic 730. Database 740 may also be accessible to external devices via, for example, Network 720.

Control Logic 730 and Analysis Logic 735 include hardware, firmware and/or software stored on a non-transitory computer readable medium. All or parts of Control Logic 730 and/or Analysis Logic 735 are optionally included within Battery Selector 130. For example, elements of Analysis Logic 735 may be included in Analysis Logic 225 and vice versa.

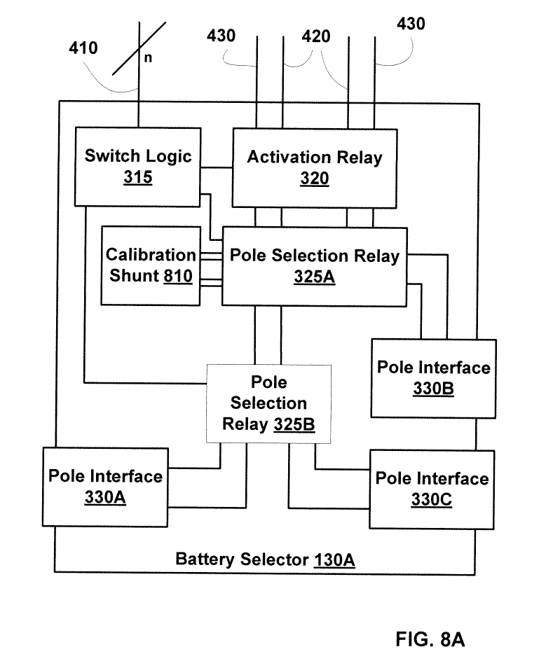

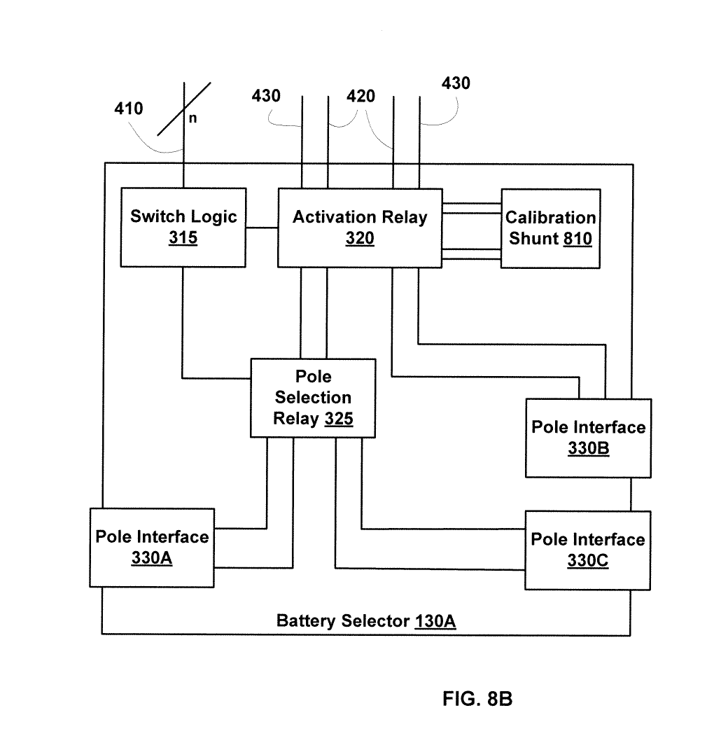

FIGS. 8A and 8B illustrate embodiments of Battery Selector 130A including a Calibration Shunt 810, according to various embodiments of the invention. Calibration Shunt 810 is configured for calibration of Battery Selector 130A. In typical embodiments Calibration Shunt 810 includes a known impedance. This impedance may include an inductance, phase angle, resistance and/or a capacitance. As such, the impedance of Calibration Shunt 810 may have a known resistance, a known impedance as a function of frequency, a known phase dependence, and a known frequency dependence. Calibration Shunt 810 may comprise inductors, resistors or capacitors and/or components having these characteristics. For example, in some embodiments Shunt 810 includes an RC circuit. In various embodiments, Calibration Shunt 810 includes a DC resistance greater than 100 micro ohms and less than 500 milli ohms. In various embodiments, Calibration Shunt 810 includes a DC resistance greater than 500 milli ohms and less than 10 ohms. Other resistance values are possible. Any or all members of Battery Selectors 130 can include instances of Calibration Shunt 810. These instances of Calibration Shunt 810 are individually addressable using Switch Logic 315 and selector selection signals generated by Selection Logic 220.

In FIG. 8A Calibration Shunt 810 is shown connected to a Pole Selection Relay 325A. In these embodiments Pole Selection Relay 325A is configured to alternatively select between making a measurement across Calibration Shunt 810 or between members of Pole Interfaces 330, in response to an output from Switch Logic 315. For example, in a first switch state of Pole Selection Relay 325A two of Sense Conductors 420 and two of Interrogation Conductors 430 are electrically coupled from Signal Bus 140 to Calibration Shunt 810. In a second switch state of Pole Selection Relay 325A one of Sense Conductor 420 and one Interrogation Conductor 430 are each electrically coupled from Signal Bus 140 to a Pole Selection Relay 325B, while the other Sense Conductor 420 and the other Interrogation Conductor 430, of Signal Bus 140, are each electrically coupled to Pole Interface 330B. Thus, in the first switch state measurements occur across Calibration Shunt 810 and in the second switch state measurements occur between the battery poles connected to Pole Interface 330B and either Pole Interface 330A or Pole Interface 330C (dependent on the state of Pole Selection Relay 325B). Pole Selection Relay 325A may include a plurality of individual relays to make this selection.

In FIG. 8B Calibration Shunt 810 is shown connected to Activation Relay 320. In these embodiments, Activation Relay 320 is configured to alternatively select between making measurements across Calibration Shunt 810 or between members of Pole Interfaces 330. For example, in a first state of Activation Relay 320 the Sense Conductors 420 and Interrogation Conductors 430 of Signal Bus 140 are not electrically coupled to anything within Battery Selector 130A (other than Activation Relay 320), in a second state Sense Conductors 420 and Interrogation Conductors 430 of Signal Bus 140 are electrically coupled to Calibration Shunt 810, and in a third state Sense Conductors 420 and Interrogation Conductors 430 of Signal Bus 140 are coupled to Pole Interface 330B and Pole Selection Relay 325. Activation Relay 320 may include a plurality of individual relays to make this selection.

Calibration Shunt 810 is typically connected to Activation Relay 320 or Pole Selection Relay 325 via at least two sense conductors and two interrogation conductors of a Kelvin probe. The testing of Calibration Shunt 810 includes sending interrogation signals to Calibration Shunt 810 via Interrogation Conductors 430 and receiving resulting signals via Sense Conductors 420. The interrogation signals may include the ranges of interrogation signal frequencies discussed elsewhere herein.

In some embodiments, testing of Calibration Shunt 810 is used to detect problems in Signal Bus 140 and/or connections thereto. For example, improperly shielded wires within Signal Bus 140 may produce undesirable results and these results may be worse at some frequencies relative to other frequencies. Testing of Calibration Shunt 810 can determine these, optionally frequency dependent, properties. In some embodiments, testing of Calibration Shunt 810 is used to characterize the various circuits between Interrogation Signal Logic 215 and Battery Selector 130A. This characterization can also include DC or frequency dependent impedance.

In some embodiments, Calibration Shunt 810 is configured for distinguishing between noise received from within the Batteries 120 and noise generated within the measurement circuits (e.g., Signal Bus 140 and/or Battery Selectors 130). For example, noise from within Batteries 120 may result from a load on Batteries 120 (e.g., a DC to AC converter), from temperature variations within Batteries 120, and/or from a charger connected to Batteries 120. Noise from the measurement circuits may result from, for example, inductance of short range AC signals, or from electromagnetic waves traveling over longer distances. Noise received from Batteries 120 can be distinguished because this noise should not be present when measuring across Calibration Shunt 810, while noise generated within the shared measurement circuits will be present whether measuring Calibration Shunt 810 or between Poles 150 of Battery 120B. As discussed elsewhere herein. Some noise can be detected by monitoring signals on Sense Conductors 420 without providing interrogation signals. In some embodiments, Analysis Logic 225 is configured to detect frequency ranges in which noise is detected and to direct Interrogation Signal Logic 215 to use frequencies at which less noise is present for testing of Batteries 120. The noise may be detected using Calibration Shunt 810.

Several embodiments are specifically illustrated and/or described herein. However, it will be appreciated that modifications and variations are covered by the above teachings and within the scope of the appended claims without departing from the spirit and intended scope thereof. For example, the relays discussed herein may be mechanical and/or solid state. Further, the systems and methods discussed herein may be applied to other electronic energy storage devices such as capacitors, and hybrid capacitor/battery systems. The systems and methods discussed herein may be applied to a wide variety of electrochemical storage device including, for example, those comprising Zinc, Alkaline, Nickel Oxyhydroxide, Lithium-ion, NiCd, Lead-Acid, NiMH, NiZn, AgZn, NiFe, Ni-Hydrogen, Li-air, Li-ion polymer, Li-Fe-Phosphate, LiS, Li-titanate, Sodium-ion, thin film lithium, ZiBr, Vanadium redox, NaS, molten salt, and Si-Oxide, as well as devices yet to be developed.

The embodiments discussed herein are illustrative of the present invention. As these embodiments of the present invention are described with reference to illustrations, various modifications or adaptations of the methods and or specific structures described may become apparent to those skilled in the art. All such modifications, adaptations, or variations that rely upon the teachings of the present invention, and through which these teachings have advanced the art, are considered to be within the spirit and scope of the present invention. Hence, these descriptions and drawings should not be considered in a limiting sense, as it is understood that the present invention is in no way limited to only the embodiments illustrated.

Computing systems referred to herein can comprise an integrated circuit, a microprocessor, a personal computer, a server, a distributed computing system, a communication device, a network device, or the like, and various combinations of the same. A computing system may also comprise volatile and/or non-volatile memory such as random access memory (RAM), dynamic random access memory (DRAM), static random access memory (SRAM), magnetic media, optical media, nano-media, a hard drive, a compact disk, a digital versatile disc (DVD), and/or other devices configured for storing analog or digital information, such as in a database. The various examples of logic noted above can comprise hardware, firmware, or software stored on a computer-readable medium, or combinations thereof. A computer-readable medium, as used herein, expressly excludes paper. Computer-implemented steps of the methods noted herein can comprise a set of instructions stored on a computer-readable medium that when executed cause the computing system to perform the steps. A computing system programmed to perform particular functions pursuant to instructions from program software is a special purpose computing system for performing those particular functions. Data that is manipulated by a special purpose computing system while performing those particular functions is at least electronically saved in buffers of the computing system, physically changing the special purpose computing system from one state to the next with each change to the stored data.

1. A battery monitoring system comprising:
a signal bus including at least two sense signal conductors, at least two interrogation signal conductors and one or more logic conductors;
a plurality of battery selectors, each of the battery selectors being configured to be electronically attached to a respective battery and each including:
switch logic configured to receive selector selection signals via the one or more logic conductors, the selector selection signals and switch logic being configured to select one of the plurality of battery selectors at a time for use in monitoring the respective battery attached to the selected one battery selector,
at least two pole interfaces, each of the pole interfaces configured to communicate an interrogation signal to a battery pole and to receive a sense signal from the respective battery pole, the interrogation signal and sense signal being communicated via separate electrical conductors of a Kelvin probe, and
an activation relay responsive to the switch logic and configured to control communication of the interrogation signal to one of the at least two pole interfaces and configured to control communication of the sense signal from one of the at least two pole interfaces; and
a central monitoring unit electrically coupled to the plurality of battery selectors by the signal bus, the central monitoring unit
configured to provide the interrogation signals to the plurality of battery selectors via the interrogation signal conductors,
configured to receive the sense signals from the plurality of battery selectors via the sense signal conductors, and
configured to send the selector selection signals to the plurality of battery selectors via the logic conductors so as to select an individual member of the plurality of battery selectors to monitor the respective battery connected thereto.

2. The system of claim 1, wherein the signal bus includes two signal conductors and two interrogation signal conductors.

3. The system of claim 1, wherein the plurality of battery selectors are connected to the signal bus in series.

4. The system of claim 1, wherein each of the plurality of battery selectors include
a first electrical connector configured to attach to the at least two sense signal conductors, the at least two interrogation signal conductors and the one or more logic conductors, and
a second electrical connector configured to attach to the at least two sense signal conductors, the at least to interrogation signal conductors and the one or more logic conductors.

5. The system of claim 1, wherein each of the plurality of battery selectors further includes a mount configured to attached the respective battery selector at a location proximate to a battery monitored using the respective battery selector.

6. The system of claim 1, wherein the selector selection signals are configured to select between monitoring the respective battery and monitoring the respective battery plus a battery strap.

7. The system of claim 1, wherein the at least two pole interfaces include
a first pole interface configured to be attached via an electrical conductor to a cathode of a first battery,
a second pole interface configured to be attached via an electrical conductor to an anode of the first battery, and
a third pole interface configured to be attached via an electrical conductor to an anode or cathode of a second battery, the second battery being connected to the first battery via a strap.

8. A battery selector comprising:
switch logic configured to receive selector selection signals, the switch logic being configured to generate an output responsive to a match between an identify of the battery selector and the received selector selection signals;
at least a first pole interface, a second pole interface and a third pole interface, each of the first, second and third pole interfaces being configured to be electrically connected to a respective battery pole using at least an interrogate conductor and a sense conductor of a respective Kelvin probe;
an activation relay
configured to open and close in response to the output of the switch logic,
configured to allow communication of interrogation signals from an external bus to at least two of the first pole interface, the second pole interface and the third pole interface when the activation relay is closed, and
configured to allow communication of sense signals to the external bus from least two of the first pole interface, the second pole interface and the third pole interface when the activation relay is closed; and
a pole selection relay
configured to open and close in response to the output of the switch logic, and
configured to select which two of the first pole interface, the second pole interface and the third pole interface are in electrical communication with the external bus responsive to the opening and closing of the pole selector relay.

9. The system of claim 8, wherein the selector selection signals include a serial signal encoding an identity of the battery selector.

10. The system of claim 8, wherein the selector selection signals include a set of parallel signals encoding an identity of a battery selector, the parallels signals being communicated to the switch logic via more than two logic conductors of the signal bus.

11. The system of claim 8, wherein the at least two pole interfaces are configured to be attached via electrical conductors to two poles, the two poles being a cathode and anode of the same battery.

12. The system of claim 8, wherein the Kelvin probe is configured to be securely attached to the respective battery pole.

13. The system of claim 8, wherein the Kelvin probe is configured to be continuously attached to the respective battery pole.

14. The system of claim 8, wherein the activation relay is rated at at least 100 Volts DC.

15. The system of claim 8, wherein the pole selection relay is rated at less than 120 Volts DC.

16. A central monitoring system comprising
a bus interface configured to be electrically connected to a signal bus;
interrogation signal logic configured to provide interrogation signals to the bus interface, the interrogation signals being further configured for detecting a state of a battery monitored by the central monitoring unit;
sensing logic configured to receive sense signals from the battery, the sense signals being in response to the interrogation signals, the sensing logic being further configured to interpret the received sense signals and generate data characterizing a state of the battery based on the interpretation;
selection logic configured to generate selection signals and to provide the generated selection signals to the bus interface, the selection signals being configured to select which one of a plurality of batteries receives the interrogation signals at a given time;
memory configured to store the data characterizing the state of the battery, for each of the plurality of batteries; and
a microprocessor configured to execute at least the sensing logic.

17. The system of claim 16, wherein the selection logic is configured to generate the selector selection signals so as to select one of the plurality of battery selectors from among at least 8 battery selectors.

18. The system of claim 16, wherein the selection logic is configured to generate selection signals so as to distinguish between a state of a battery and a state of the battery plus a strap attached to the battery.

19. The system of claim 16, wherein the interrogation signals include time dependent signals having a frequency between 70 and 100 Hz.

20. The system of claim 16, wherein the interrogation signals include time dependent signals having a frequency between 0.1 and 10 Hz.

21. The system of claim 16, wherein the sensing logic is configured to measure phase differences between the interrogation signals and the sense signals.

22. The system of claim 16, wherein the sensing logic is configured to measure sense signals from a battery for a period greater than one minute, the sense signals having a frequency between 0.01 and 10 Hz.

23. The system of claim 16, wherein the selection logic is configured to generate selection signals so as to select each of the batteries for monitoring, and to select to include a battery strap in the monitoring.
